(19) United States
(12) Patent Application Publication
(10) Pub. No.: US 2009/0256168 A1
(43) Pub. Date: Oct. 15, 2009

(54) DISPLAY ELEMENT, MANUFACTURING METHOD OF THE SAME AND DISPLAY DEVICE

(75) Inventors: Takayuki Taneda, Kanagawa (JP); Katsuhide Uchino, Kanagawa (JP); Tetsuro Yamamoto, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: Sony Corporation, Tokyo (JP)

(21) Appl. No.: 12/421,221

(22) Filed: Apr. 9, 2009

(30) Foreign Application Priority Data
Apr. 11, 2008 (JP) 2008-103823

(51) Int. Cl. H01L 33/00; H01L 21/28

(52) U.S. Cl. 257/98; 438/29; 257/40; 257/E33.061; 257/E21.158

(57) ABSTRACT

A display element including: a first electrode; an auxiliary wiring formed on the periphery of the first electrode in such a manner as to be insulated from the first electrode; an insulating portion having first and second openings, the first opening adapted to expose the first electrode, and the second opening adapted to expose the auxiliary wiring, an organic layer adapted to cover at least the exposed surface of the first electrode in the first opening; and a second electrode adapted to cover at least the organic layer and the exposed surface of the auxiliary wiring in the second opening, wherein the organic layer has a layered structure which includes at least a hole injection layer and light-emitting layer stacked in this order from the side of the first electrode, and the edge of the hole injection layer is provided more inward than the edge of the organic layer.

### BACKGROUND OF THE INVENTION

1. Field of the Invention

The present invention relates to a self-luminous display element such as organic light-emitting element, manufacturing method of the same and display device having the same.

2. Description of the Related Art

Recent years have seen the commercialization of organic EL (electroluminescence) displays using organic light-emitting elements as a substitute for liquid crystal displays. Organic EL displays are self-luminous and therefore have a wider view angle than liquid crystal displays. Further, this type of display is considered to offer sufficiently rapid response to a high-definition high-speed video signal.

An organic EL display can be manufactured, for example, as described below. First, as illustrated in FIG. 18A, pixel drive circuits (not shown) are formed, one for each pixel, on a substrate 111. Each drive circuit includes a drive transistor Tr1. Next, photosensitive resin is applied over the entire surface to form a planarizing insulating film 112. Then, the same film 112 is patterned into a predetermined form through exposure and development. At the same time, a connection hole 112A is formed on each of the drive transistors Tr1, after which the substrate is fired.

Next, as illustrated in FIG. 18B, a conductive layer (not shown) is formed by sputtering over the entire surface, followed by selective removal of the conductive layer through wet etching. This forms not only a first electrode 113 in each subpixel region 110A (region in which an organic light-emitting element is formed) but also an auxiliary electrode 114 on the periphery of the subpixel region 110A. The first electrode 113 is connected to the drive transistor Tr1 via a connection hole 112A.

Next, as illustrated in FIG. 19A, photosensitive resin (not shown) is applied over the entire surface. Then, an opening portion 115A is made for the first electrode 113 through exposure and development. At the same time, an opening portion 115B is made for the auxiliary electrode 114, after which the substrate is fired to form an isolation insulating film 115.

Next, as illustrated in FIG. 19B, a mask (not shown) is disposed in proximity to the surface. The mask has opening portions for the opening portions 115A. Then, a hole injection layer 116A, hole transporting layer 116B, light-emitting layer 116C and electron transporting layer 116D are sequentially formed, for example, through vapor deposition on the exposed surface of the first electrode 113 in the opening portion 115A, thus forming an organic layer 116.

Next, as illustrated in FIG. 20A, a second electrode 117 is formed over the entire surface, for example, through vapor deposition. This connects the second electrode 117 to the auxiliary electrode 114 via the opening portion 115B. It should be noted that the auxiliary electrode 114 is provided to ensure reduced resistance of the second electrode 117.

Next, as illustrated in FIG. 20B, a protective film 118 and adhesive layer 119 are sequentially formed on the second electrode 117. Then, a sealing substrate 120 having a color filter 121 formed thereon is attached to the adhesive layer 119 in such a manner that the color filter 121 faces the adhesive layer 119. This is how an organic EL display is formed.

In the organic EL display having an organic light-emitting element formed as described above for each pixel, the drive transistor Tr1 in each pixel is turned on and off in a controlled manner to supply a drive current to the light-emitting element in each pixel. This allows holes and electrons to recombine, thus causing light emission. This light is multiply reflected between the first and second electrodes 113 and 117, after which the light passes through the second electrode 117, protective film 118, adhesive layer 119, color filter 121 and sealing substrate 120 and then is extracted.

It should be noted that the configuration of the organic light-emitting element is disclosed, for example, in Japanese Patent Laid-Open No. 2007-234581.

### SUMMARY OF THE INVENTION

Incidentally, the above organic light-emitting element has a drawback in that its V-I characteristic often deviates from the ideal condition. This leads to improper driving of the pixels, resulting in deterioration of the organic light-emitting element over time and difficulties in suppressing the characteristic variations of the drive transistor.

The present invention has been devised in light of the above problems, and it is desirable for the present invention to provide a display element capable of preventing the deviation of its V-I characteristic from the ideal condition, manufacturing method of the same and display device having the same.

A first display element of an embodiment of the present invention has an organic layer between first and second electrodes. An auxiliary wiring is formed around the first electrode in such a manner as to be insulated from the first electrode. Further, an insulating portion is formed which has first and second openings. The first opening exposes the first electrode, and the second opening the auxiliary wiring. The organic layer covers at least the exposed surface of the first electrode in the first opening. The second electrode covers at least the organic layer and the exposed surface of the auxiliary wiring in the second opening. The edge of a hole injection layer is provided more inward than the edge of the organic layer.

A first display device of another embodiment of the present invention includes the above first display element and drive circuits adapted to drive the first display element.

In the first display element and first display device of the embodiments of the present invention, the edge of the hole injection layer is provided more inward than the edge of the organic layer. This allows for a layer of the organic layer other than the hole injection layer to mediate between the hole injection layer and second electrode, thus keeping the hole injection layer and second electrode out of contact with each other.

A second display element of an embodiment of the present invention has an organic layer between first and second electrodes. An auxiliary wiring is formed around the first electrode in such a manner as to be insulated from the first electrode. Further, an insulating portion is formed which has first and second openings. The first opening exposes the first electrode, and the second opening the auxiliary wiring. The organic layer covers at least the exposed surface of the first electrode in the first opening. The second electrode covers at least the organic layer and the exposed surface of the auxiliary wiring in the second opening. The edge of a hole injection layer has higher resistance than the middle portion of the same layer.

A second display device of another embodiment of the present invention includes the above second display element and drive circuits adapted to drive the second display element.

In the second display element and second display device of the embodiments of the present invention, the edge of the hole injection layer has higher resistance than the middle portion of the same layer. This allows for a high-resistance portion (edge of the hole injection layer) to mediate between the middle portion of the hole injection layer and the second electrode, thus keeping the low-resistance portion (middle portion of the hole injection layer) and second electrode out of contact with each other.

A manufacturing method of a first display element of an embodiment of the present invention includes the following steps A1 to A4:

A1: Step of forming a first electrode and an auxiliary wiring on the edge of the first electrode on a substrate in such a manner that the auxiliary wiring is insulated from the first electrode

A2: Step of forming an insulating portion having a first opening adapted to expose the first electrode and a second opening adapted to expose the auxiliary wiring

A3: Step of forming a hole injection layer adapted to cover at least the exposed surface of the first electrode in the first opening first, and then forming an organic layer, which is less conductive than the hole injection layer and which includes a light-emitting layer, in such a manner as to cover the hole injection layer

A4: Step of forming a second electrode adapted to cover at least the organic layer and the exposed surface of the auxiliary wiring in the second opening The manufacturing method of the first display element of the embodiment of the present invention forms the organic layer in such a manner as to cover the hole injection layer. The organic layer is less conductive than the hole injection layer and includes a light-emitting layer. As a result, the edge of the hole injection layer is provided more inward than the edge of the organic layer. This allows for the organic layer to mediate between the hole injection layer and second electrode, thus keeping the hole injection layer and second electrode out of contact with each other.

A manufacturing method of a second display element of another embodiment of the present invention includes the following steps B1 to B5:

B1: Step of forming a first electrode and an auxiliary wiring on the edge of the first electrode on a substrate in such a manner that the auxiliary wiring is insulated from the first electrode

B2: Step of forming an insulating portion having a first opening adapted to expose the first electrode and a second opening adapted to expose the auxiliary wiring

B3: Step of forming a hole injection layer adapted to cover at least the exposed surface of the first electrode in the first opening and at the same time providing the edge of the hole injection layer with higher resistance than the middle portion of the same layer

B4: Step of forming an organic layer, which is less conductive than the hole injection layer and which includes a light-emitting layer, on the hole injection layer

B5: Step of forming a second electrode adapted to cover at least the organic layer and the exposed surface of the auxiliary wiring in the second opening

The manufacturing method of the second display element of the embodiment the present invention provides the edge of the hole injection layer with higher resistance than the middle portion of the same layer. This allows for a high-resistance portion (edge of the hole injection layer) to mediate between the middle portion of the hole injection layer and the second electrode, thus keeping the low-resistance portion (middle portion of the hole injection layer) and second electrode out of contact with each other.

According to the first display element and first display device of the embodiments of the present invention, a layer of the organic layer other than the hole injection layer mediates between the hole injection layer and second electrode, thus keeping the hole injection layer and second electrode out of contact with each other. This provides reduced current (leak current) flowing between the first and second electrodes without flowing via the light-emitting layer, thus preventing the deviation of the V-I characteristic from the ideal condition.

According to the manufacturing method of the first display element of the embodiment of the present invention, the organic layer mediates between the hole injection layer and second electrode, thus keeping the hole injection layer and second electrode out of contact with each other. This provides reduced current (leak current) flowing between the first and second electrodes without flowing via the light-emitting layer, thus preventing the deviation of the V-I characteristic from the ideal condition.

According to the second display element, second display device and manufacturing method of the second display element of the embodiments of the present invention, a high-resistance portion (edge of the hole injection layer) mediates between the hole injection layer and second electrode, thus keeping the low-resistance portion (middle portion of the hole injection layer) and second electrode out of contact with each other. This provides reduced current (leak current) flowing between the first and second electrodes without flowing via the light-emitting layer, thus preventing the deviation of the V-I characteristic from the ideal condition.

### BRIEF DESCRIPTION OF THE DRAWINGS

FIG. 1 is a configuration diagram of a display device according to a first embodiment of the present invention;

FIG. 2 is a diagram illustrating an example of a pixel drive circuit;

FIG. 3 is a sectional configuration diagram of an organic light-emitting element shown in FIG. 1;

FIG. 4 is a plan configuration diagram of a first electrode and auxiliary wiring;

FIGS. 5A and 5B are sectional configuration diagrams for describing the manufacturing steps of the display device shown in FIG. 1;

FIGS. 6A and 6B are sectional configuration diagrams continued from FIGS. 5A and 5B for describing the manufacturing steps;

FIGS. 7A and 7B are sectional configuration diagrams continued from FIGS. 6A and 6B for describing the manufacturing steps;

FIG. 8 is a configuration diagram of a display device according to a second embodiment of the present invention;

FIG. 9 is a sectional configuration diagram for describing the manufacturing steps of the display device shown in FIG. 8;

FIG. 10 is a configuration diagram of a display device according to a third embodiment of the present invention;

FIGS. 11A and 11B are sectional configuration diagrams for describing the manufacturing steps of the display device shown in FIG. 10;

FIG. 12 is a plan view illustrating the schematic configuration of a module containing the display device according to the above embodiments;

FIG. 13 is a perspective view illustrating the appearance of application example 1 of the display device according to the above embodiments;

FIG. 14A is a perspective view illustrating the appearance of application example 2 as seen from the front, and 14B a perspective view illustrating the appearance of application example 2 as seen from the rear;

FIG. 15 is a perspective view illustrating the appearance of application example 3;

FIG. 16 is a perspective view illustrating the appearance of application example 4;

FIG. 17A is a front view of application example 5 in an open position, FIG. 17B is a side view thereof, FIG. 17C is a front view thereof in a closed position, FIG. 17D is a left side view thereof, FIG. 17E is a right side view thereof, FIG. 17F is a top view thereof, and FIG. 17G is a bottom view thereof;

FIGS. 18A and 18B are sectional configuration diagrams for describing the manufacturing steps of an existing display device;

FIGS. 19A and 19B are sectional configuration diagrams continued from FIGS. 18A and 18B for describing the manufacturing steps; and

FIGS. 20A and 20B are sectional configuration diagrams continued from FIGS. 19A and 19B for describing the manufacturing steps.

### DETAILED DESCRIPTION OF THE PREFERRED EMBODIMENTS

The preferred embodiments of the present invention will be described in detail below with reference to the accompanying drawings.

### First Embodiment

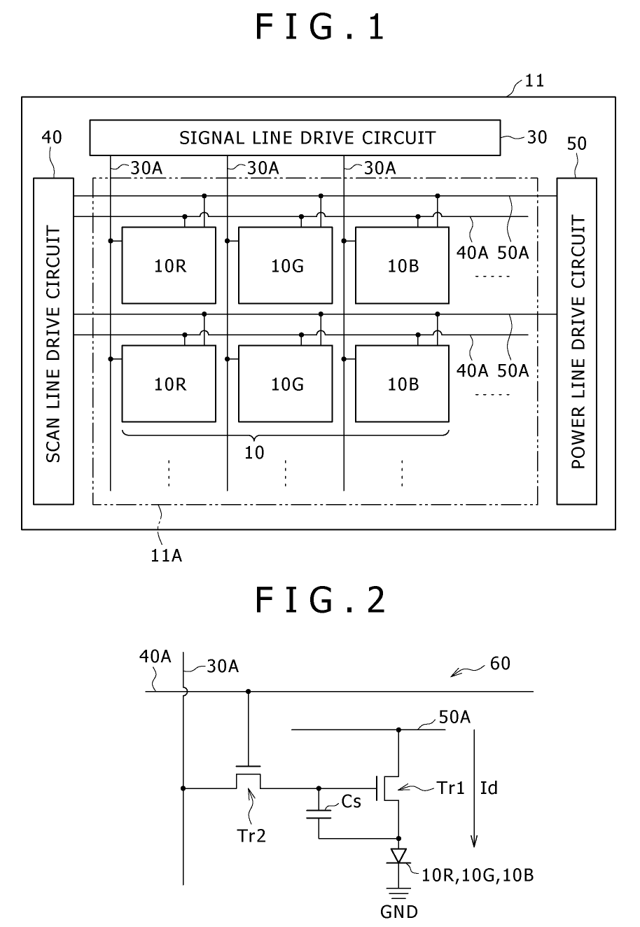

FIG. 1 is a diagram illustrating the configuration of a display device using organic light-emitting elements 10R, 10G and 10B according to a first embodiment of the present invention. This display device is used as an ultra-slim organic light-emitting color display. The display device has a display area 11A formed on a substrate 11 made, for example, of glass, silicon (Si) wafer or resin. A plurality of organic light-emitting elements 10R, 10G and 10B are arranged in a matrix form in the display area 11A. Video display drivers, i.e., a signal line drive circuit 30, scan line drive circuit 40 and power line drive circuit 50, are formed around the display area 11A.

Pixel drive circuits 60 as illustrated in FIG. 2 are formed in the display area 11A. The pixel drive circuits 60 are each formed on the underlying layer of a first electrode 13 which will be described later. The same circuit 60 is an active drive circuit which includes the drive transistor Tr1, a write transistor Tr2, a capacitor (holding capacitance) Cs, and an organic light-emitting element 10R (or 10G or 10B). The capacitor is provided between the drive transistor Tr1 and write transistor Tr2. The organic light-emitting element 10R (or 10G or 10B) is connected in series to the drive transistor Tr1 between a power line 50A and ground (GND). The drive transistor Tr1 and write transistor Tr2 are both formed with a typical thin film transistor (TFT). These transistors are not limited in their configuration and may have a reverse-staggered structure (so-called bottom gate transistor) or staggered structure (top gate transistor).

In the pixel drive circuit 60, a plurality of signal lines 30A are arranged in the column direction, and a plurality of scan lines 40A in the row direction. Each of the intersections between one of the signal lines 30A and one of the scan lines 40A is associated with the organic light-emitting element 10R, 10G or 10B (subpixel) The signal lines 30A are all connected to the signal line drive circuit 30. An image signal is supplied to the source electrode of the write transistor Tr2 from the signal line drive circuit 30 via the signal line 30A. The scan lines 40A are all connected to the scan line drive circuit 40. A scan signal is sequentially supplied to the gate electrode of the write transistor Tr2 from the scan line drive circuit 40 via the scan line 40A.

Further, the organic light-emitting elements 10R, 10G and 10B adapted respectively to produce red light, green light and blue light are formed sequentially in a matrix form as a whole in the display area 11A. It should be noted that the combination of the organic light-emitting elements 10R, 10G and 10B adjacent to each other makes up a single pixel 10.

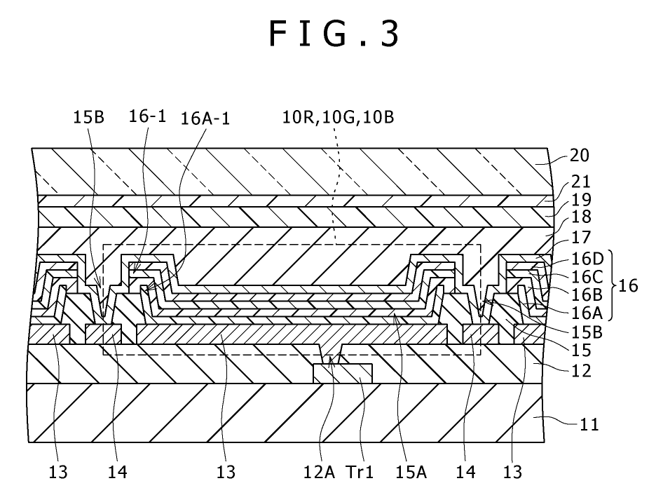

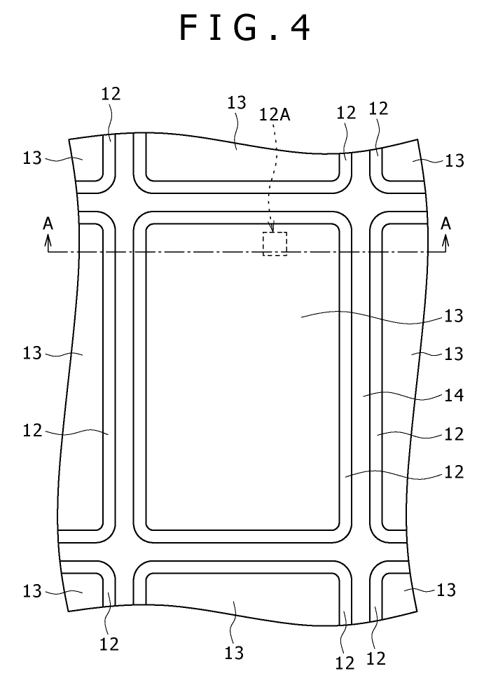

FIG. 3 illustrates the sectional configuration shared by all the organic light-emitting elements 10R, 10G and 10B. FIG. 4 diagrammatically illustrates the plan configuration in the same plane as the first electrode 13 which will be described later. The drive transistor Tr1 of the pixel drive circuit 60 and a planarizing insulating film 12 are formed sequentially in this order on the substrate 11 from the side of the substrate 11. The organic light-emitting elements 10R, 10G and 10B are formed on the planarizing insulating film 12.

The drive transistor Tr1 is electrically connected to the first electrode 13 (described later) via a connection hole 12A provided in the planarizing insulating film 12. The planarizing insulating film 12 is designed to planarize the surface of the substrate 11 on which the pixel drive circuit 60 is formed. The fine connection holes 12A are formed in the same film 12. Therefore, the planarizing insulating film 12 should preferably be formed with a material that offers an excellent patterning accuracy. Among possible choices of materials for the same film 12 are organic materials such as polyimide and inorganic materials such as silicon oxide (SiO₂).

The organic light-emitting elements 10R, 10G and 10B each include the first electrode 13, the organic layer 16 and a second electrode 17 which are stacked sequentially in this order from the side of the substrate 11. The first electrode 13 serves as an anode, and the second electrode 17 as a cathode. As illustrated in FIG. 4, an auxiliary wiring 14 is formed around the first electrode 13 in the same plane as the first electrode 13 so as to surround the same electrode 13. The auxiliary wiring 14 is disposed with a predetermined gap from the first electrode 13 so that the auxiliary wiring 14 is insulated from the first electrode 13. Further, an isolation insulating film 15 (insulating portion) is formed around the first electrode 13. The isolation insulating film 15 has first and second openings 13A and 13B. The first opening 13A exposes the first electrode 13, and the second opening 13B the auxiliary wiring 14. The organic layer 16 covers at least the exposed surface of the first electrode 13 in the first opening 13A. The second electrode 17 covers at least the organic layer 16 and the exposed surface of the auxiliary wiring 14 in the second opening 13B. It should be noted that FIG. 3 illustrates a case in which the organic layer 16 covers the exposed surface of the first electrode 13 in the first opening 13A and part of the isolation insulating film 15, and in which the second electrode 17 covers the organic layer 16, exposed surface of the auxiliary wiring 14 in the second opening 13B and area of the isolation insulating film 15 not covered by the organic layer 16 (that is, the second electrode 17 is formed over the entire surface of the organic light-emitting element 10R, 10G or 10B on the opposite side of the substrate 11).

Incidentally, in the organic light-emitting element 10R, 10G or 10B, the first electrode 13 can serve as a reflecting layer, and the second electrode 17 as a semi-transmissive reflecting layer. The first and second electrodes 13 and 17 form a resonator structure adapted to cause light, produced by a light-emitting layer 16C (described later) of the organic layer 16, to resonate.

That is, in the organic light-emitting element 10R, 10G or 10B, the end surface of the first electrode 13 on the side of the organic layer 16 and that of the second electrode 17 on the side of the same layer 16 make up a pair of reflecting mirrors. The two electrodes 13 and 17 thus form a resonator structure adapted to cause light, produced by the light-emitting layer 16C, to resonate by means of this pair of reflecting mirrors for extraction of the produced light from the side of the second electrode 17. This leads to multiple interference of the light produced by the light-emitting layer 16C. Because the resonator structure functions as a kind of narrow-band filter, the half width of the spectrum of the extracted light will diminish, providing improved color purity. Further, external light incident from the side of a sealing substrate 20 can be attenuated by multiple interference. This makes it possible to reduce the reflectance of the organic light-emitting elements 10R, 10G and 10B for external light to an extremely small level by using a color filter 52, which will be described later, or a phase plate and polarizers (not shown) in combination.

The first electrode 13 serves also as a reflecting layer as described above. Therefore, the same electrode 13 should preferably have as high a reflectance as possible in order to achieve high light emission efficiency. The first electrode 13 is made of a single metal element such as chromium (Cr), gold (Au), platinum (Pt), nickel (Ni), copper (Cu), tungsten (W) or silver (Ag) or an alloy of these elements. The thickness of the same electrode 13 in the stacking direction (hereinafter referred simply as thickness) is, for example, between 100 nm and 1000 nm.

The auxiliary wiring 14 is provided to ensure uniformity of the potential distribution across the surface of the second electrode 17. The same wiring 14 is formed in the same plane as the first electrode 13 as described above. Therefore, the same wiring 14 should preferably be made of the same material as the first electrode 13. This allows for the auxiliary wiring 14 and first electrode 13 to be manufactured in the same step, thus contributing to simpler manufacturing steps.

The isolation insulating film 15 is designed to ensure insulation between the first and second electrodes 13 and 17 and form the light-emitting area of the light-emitting layer 16C into exactly the desired shape. The same film 15 is made, for example, of photosensitive resin. The first opening 13A is provided in the isolation insulating film 15 for the light-emitting area. It should be noted that the organic layer 16 and second electrode 17 are provided continuously not only on the first electrode 13 but also on the isolation insulating film 15. However, light is produced only from the portion of the light-emitting layer 16C in proximity to the first electrode 13.

The organic layer 16 has a layered structure which includes, for example, a hole injection layer 16A, hole transporting layer 16B, light-emitting layer 16C and electron transporting layer 16D stacked in this order from the side of the first electrode 13. In this layered structure, an edge 16A-1 (refer to FIG. 3) of the hole injection layer 16A is provided more inward (closer to the light-emitting area) than an edge 16-1 of the entire organic layer 16. Therefore, a layer of the organic layer 16 other than the hole injection layer 16A (hole transporting layer 16B in FIG. 3) mediates between the hole injection layer 16A and second electrode 17, thus keeping the hole injection layer 16A and second electrode 17 out of contact with each other.

It should be noted that the organic layer 16 may, as necessary, include other layers in addition to those illustrated and be devoid of the hole transporting layer 16B and light-emitting layer 16C. Further, the organic layer 16 may have different configurations depending on the colors of light emitted by the organic light-emitting elements 10R, 10G and 10B.

The hole injection layer 16A is designed to ensure enhanced hole injection efficiency. The hole transporting layer 16B is designed to ensure enhanced efficiency of hole transport to the light-emitting layer 16C. The light-emitting layer 16C is designed to cause recombination of electrons and holes by means of an electric field generated between the first and second electrodes 13 and 17 so as to produce light. The electron transporting layer 16D is designed to ensure enhanced efficiency of electron transport to the light-emitting layer 16C. It should be noted that an electron injection layer (not shown), made of LiF, Li₂O or other material, may be provided between the electron transporting layer 16D and second electrode 17.

Here, in the case of the organic light-emitting element 10R, the hole injection layer 16A is made, for example, of 4,4′,4″-tris(3-methylphenylphenylamino)triphenylamine (m-MTDATA) or 4,4′,4″-tris(2-naphthylphenylamino)triphenylamine(2-TNATA). The thickness thereof is, for example, between 5 nm and 300 nm. The hole transporting layer 16B is made, for example, of bis[(N-naphthyl)-N-phenyl]benzidine(α-NPD). The thickness thereof is, for example, between 5 nm and 300 nm. The light-emitting layer 16C is made, for example, of 8-quinolinol aluminum complex (Alq₃) mixed with 40 volume percent of 2,6-bis[4-[N-(4-methoxyphenyl)-N-phenyl]aminostyryl]naphthalene-1,5-dicarbonitrile (BSN-BCN). The thickness thereof is, for example, between 10 nm and 100 nm. The electron transporting layer 16D is made of Alq₃. The thickness thereof is, for example, between 5 nm and 300 nm.

In the case of the organic light-emitting element 10G, the hole injection layer 16A is made, for example, of m-MTDATA or 2-TNATA. The thickness thereof is, for example, between 5 nm and 300 nm. The hole transporting layer 16B is made, for example, of α-NPD. The thickness thereof is, for example, between 5 nm and 300 nm. The light-emitting layer 16C is made, for example, of Alq₃ mixed with 3 volume percent of coumarin 6. The thickness thereof is, for example, between 10 nm and 100 nm. The electron transporting layer 16D is made, for example, of Alq₃. The thickness thereof is, for example, between 5 nm and 300 nm.

In the case of the organic light-emitting element 10B, the hole injection layer 16A is made, for example, of m-MTDATA or 2-TNATA. The thickness thereof is, for example, between 5 nm and 300 nm. The hole transporting layer 16B is made, for example, of α-NPD. The thickness thereof is, for example, between 5 nm and 300 nm. The light-emitting layer 16C is made, for example, of spiro6Φ. The thickness thereof is, for example, between 10 nm and 100 nm. The electron transporting layer 16D is made, for example, of Alq₃. The thickness thereof is, for example, between 5 nm and 300 nm.

The second electrode 17 is made of a single metal element such as aluminum (Al), magnesium (Mg), calcium (Ca) and sodium (Na) or an alloy of these elements. Above all, the same electrode 17 should preferably be made of a magnesium-silver alloy (MgAg alloy) or aluminum (Al)-lithium (Li) alloy (AlLi alloy). The thickness thereof is, for example, between 5 nm and 50 nm.

In the present embodiment, the organic light-emitting elements 10R, 10G and 10B are covered with a protective film 18 made of silicon nitride (SiNx) or other material. Further, the sealing substrate 20 is attached over the entire surface of the protective film 18 for sealing purposes with an adhesive layer 19 provided therebetween.

The adhesive layer 19 is made, for example, of thermo-setting or ultraviolet-setting resin.

The sealing substrate 20 is positioned on the side of the second electrode 17 of the organic light-emitting elements 10R, 10G and 10B and designed, together with the adhesive layer 19, to seal the same elements 10R, 10G and 10B. The sealing substrate 20 is made of glass or other material which is transparent for light produced by the organic light-emitting elements 10R, 10G and 10B. The sealing substrate 20 has, for example, a color filter 21. The same filter 21 extracts light produced by the organic light-emitting elements 10R, 10G and 10B and absorbs external light reflected by the wirings provided therebetween, thus ensuring enhanced contrast.

The color filter 21 may be provided on either side of the sealing substrate 20. However, the same filter 21 should preferably be provided on the side of the organic light-emitting elements 10R, 10G and 10B. One reason for this is that the color filter 21 remains unexposed from the surface and therefore can be protected by the adhesive layer 19. Another reason is that it is possible to prevent mixture of colors which is caused by light from the light-emitting layer 16C entering the adjacent color filter 21 of other color. This mixture of colors can be prevented thanks to a smaller distance between the light-emitting layer 16C and color filter 21. The color filter 21 has red, green and blue filters (not shown) which are provided to be associated with the organic light-emitting elements 10R, 10G and 10B.

The red, green and blue filters are rectangular in shape and formed with no gap therebetween. Each of these filters is made of a resin mixed with a pigment. The resin-pigment mixture is adjusted by selection of the pigment so as to provide a high optical transmittance in the intended red, green or blue range of wavelengths and a low optical transmittance in other ranges of wavelengths.

Further, the range of wavelengths of the color filter 21 that provides a high transmittance matches the peak wavelength of the spectrum of the desired light to be extracted from the resonator structure. This ensures that only the portion of external light having the same wavelength as the peak wavelength of the desired light passes through the color filter 21, thus preventing the entry of external light having any other wavelengths into the organic light-emitting elements 10R, 10G and 10B.

This display device can be manufactured, for example, in the following manner.

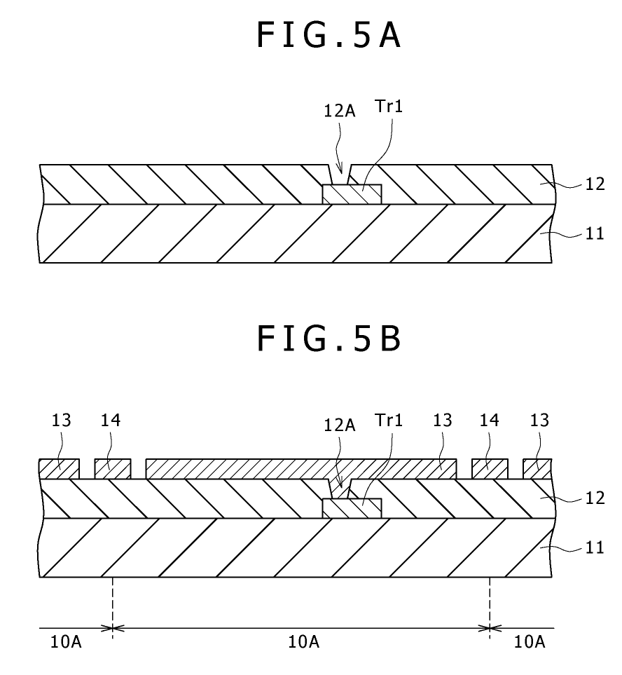

FIGS. 5A and 5B to FIGS. 7A and 7B illustrate the manufacturing steps of the display device. First, as illustrated in FIG. 5A, the pixel drive circuits 60 (not shown), one for each pixel, are formed on the substrate 11. Each drive circuit 60 includes the drive transistor Tr1. Next, photosensitive resin is applied over the entire surface to form the planarizing insulating film 12. Then, the same film 12 is patterned into a predetermined form through exposure and development. At the same time, the connection hole 12A is formed on each of the drive transistors Tr1, after which the substrate is fired.

Next, as illustrated in FIG. 5B, a conductive layer (not shown) is formed by sputtering over the entire surface, followed by selective removal of the conductive layer through wet etching. This forms not only the first electrode 13 in each subpixel region 10A (region in which the organic light-emitting elements 10R, 10G and 10B) are formed but also an auxiliary electrode 14 on the periphery of the subpixel region 10A. The first electrode 13 is connected to the drive transistor Tr1 via a connection hole 12A.

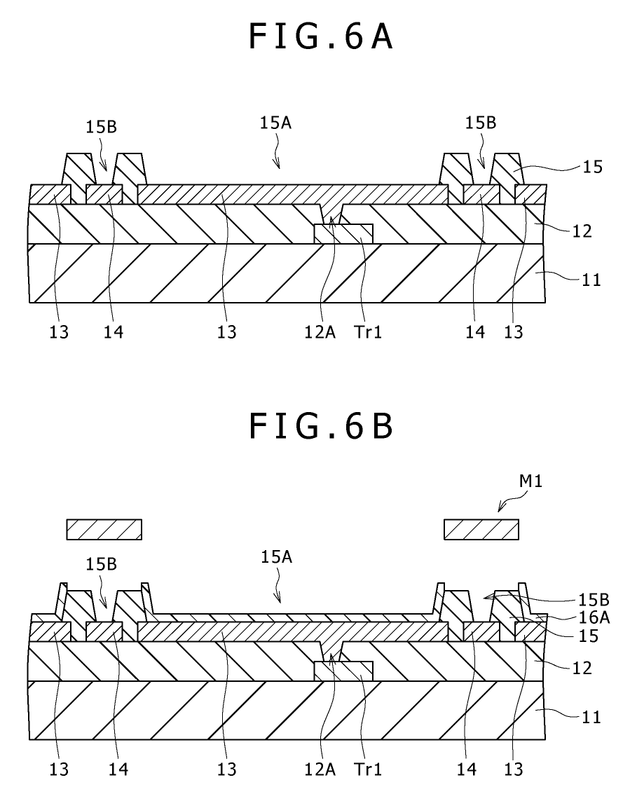

Next, as illustrated in FIG. 6A, photosensitive resin (not shown) is applied over the entire surface. Then, an opening portion 15A is made for the first electrode 13 through exposure and development. At the same time, an opening portion 15B is made for the auxiliary electrode 14, after which the substrate is fired to form the isolation insulating film 15.

Next, as illustrated in FIG. 6B, a mask M1 is disposed in proximity to the surface. The mask has opening portions for the opening portions 15A. Then, a hole injection layer 16A is formed, for example, through vapor deposition on the exposed surface of the first electrode 13 in the opening portion 15A.

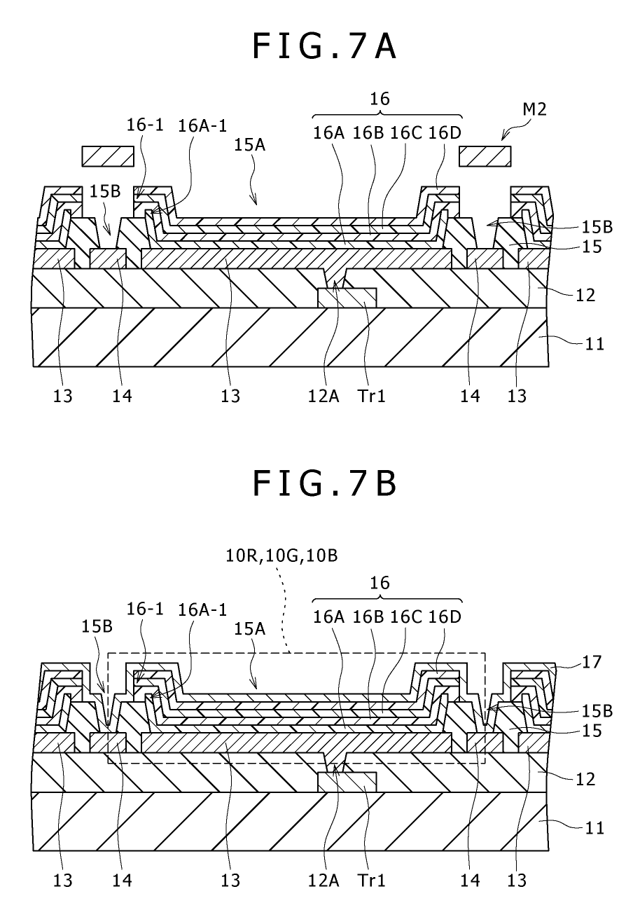

Next, as illustrated in FIG. 7A, a mask M2 is disposed in proximity to the surface. The mask M2 has opening portions having a larger opening area than that of the opening portions of the mask M1. Then, organic layers (hole transporting layer 16B, light-emitting layer 16C and electron transporting layer 16D) which are less conductive than the hole injection layer 16A are sequentially formed, for example, through vapor deposition on the surface of the hole injection layer 16A and that of the portion of the isolation insulating film 15 adjacent to the same layer 16A, thus forming the organic layer 16.

Next, as illustrated in FIG. 7B, the second electrode 17 is formed over the entire surface, for example, through vapor deposition. This connects the second electrode 17 to the auxiliary electrode 14 via the opening portion 15B. This is how the organic light-emitting elements 10R, 10G and 10B according to the present embodiment are formed.

Next, as illustrated in FIG. 3, the protective film 18 and adhesive layer 19 are sequentially formed on the second electrode 17. Then, the sealing substrate 20 having the color filter 21 formed thereon is attached to the adhesive layer 19 in such a manner that the color filter 21 faces the adhesive layer 19. This is how the display device according to the present embodiment is formed.

In the organic EL display having an organic light-emitting element formed as described above in each pixel, the drive transistor Tr1 in each pixel is turned on and off in a controlled manner to supply a drive current to the light-emitting element in each pixel. This allows holes and electrons to recombine, thus causing light emission. This light is multiply reflected between the first and second electrodes 13 and 17, after which the light passes through the second electrode 17, protective film 18, adhesive layer 19, color filter 21 and sealing substrate 20 and then is extracted.

Incidentally, in the present embodiment, the edge 16A-1 (refer to FIG. 3) of the hole injection layer 16A is provided more inward (closer to the light-emitting area) than the edge 16-1 of the entire organic layer 16. Therefore, a layer of the organic layer 16 other than the hole injection layer 16A (hole transporting layer 16B in FIG. 3) mediates between the hole injection layer 16A and second electrode 17, thus keeping the hole injection layer 16A and second electrode 17 out of contact with each other. This provides reduced current (leak current) flowing between the first and second electrodes 13 and 17 without flowing via the light-emitting layer 16C, thus preventing the deviation of the V-I characteristic from the ideal condition.

### Second Embodiment

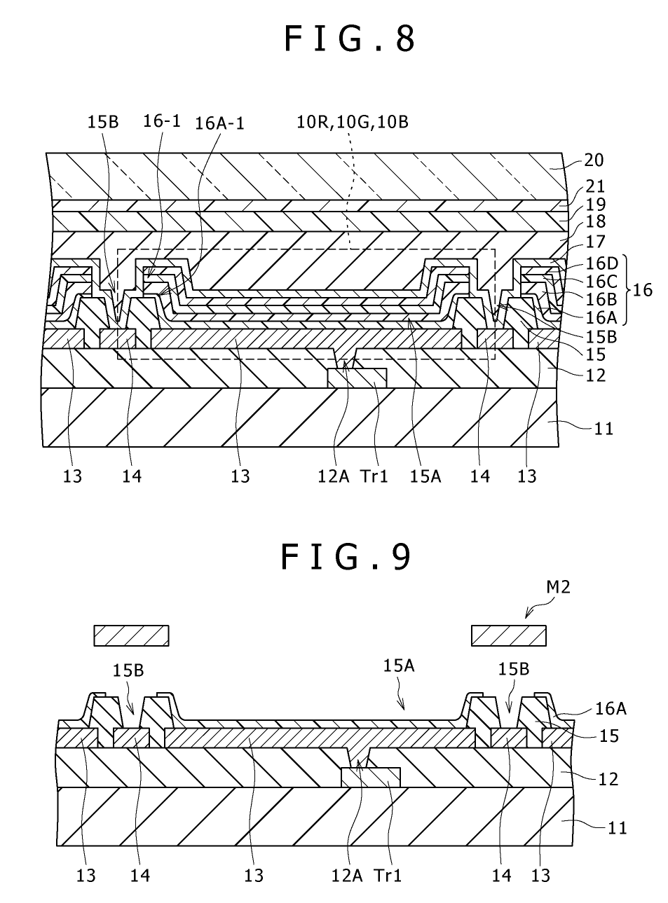

FIG. 8 illustrates a sectional configuration of the organic light-emitting elements 10R, 10G and 10B in a display device according to a second embodiment of the present invention. This display device differs from that configured according to the first embodiment in that the edge 16A-1 of the hole injection layer 16A is thinner than the middle portion of the same layer 16A (portion other than the edge 16A-1 of the hole injection layer 16A). Therefore, the differences will be primarily described below, and the description of the commonalities will be omitted as appropriate.

In the present embodiment, the edge 16A-1 of the hole injection layer 16A is thinner than the middle portion of the same layer 16A (portion other than the edge 16A-1 of the hole injection layer 16A) as illustrated in FIG. 8. The thickness of the edge 16A-1 is, for example, approximately less than half the thickness of the middle portion of the hole injection layer. As a result, the conductivity of the edge 16A-1 is lower than that of the middle portion, commensurate with the reduction in its thickness.

The hole injection layer 16A can be formed, for example, as described below. As illustrated in FIG. 9A, a mask M3 is disposed farther from the substrate 11 than where the mask M1 was disposed. The mask M3 has opening portions having a smaller opening area than that of the opening portions of the mask M1. Then, the hole injection layer 16A is formed primarily on the bottom surface of the opening portion 15A, for example, through vapor deposition. At this time, because the mask M3 is disposed far from the substrate 11, the vapor-deposited material adheres also to part of the isolation insulating film 15, thus forming a thin film of the hole injection layer 16A on the isolation insulating film 15. It should be noted that the mask M3 need only be disposed low to form the edge 16A-1 of the hole injection layer 16A thin, and that the mask M3 need only be disposed high to form the same edge 16A-1 thick. It should also be noted that the hole injection layer 16A according to the present embodiment may be formed by other method.

In the present embodiment, the edge 16A-1 of the hole injection layer 16A is thinner than the middle portion of the same layer 16A, and the conductivity of the edge 16A-1 is lower than that of the middle portion, commensurate with the reduction in its thickness. This allows for the high-resistance portion (edge 16A-1 of the hole injection layer 16A) to mediate between the middle portion of the hole injection layer 16A and the second electrode 17, thus keeping the low-resistance portion (middle portion of the hole injection layer 16A) and second electrode 17 out of contact with each other. This provides reduced current (leak current) flowing between the first and second electrodes 13 and 17 without flowing via the light-emitting layer 16C, thus preventing the deviation of the V-I characteristic from the ideal condition.

### Third Embodiment

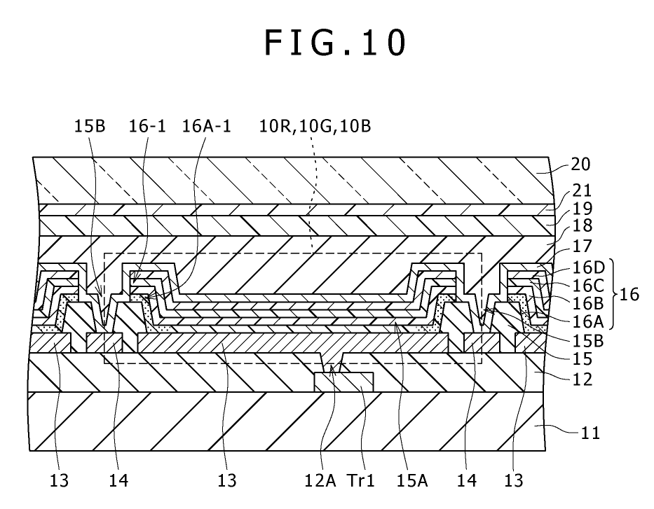

FIG. 10 illustrates an example of sectional configuration of the organic light-emitting elements 10R, 10G and 10B in a display device according to a third embodiment of the present invention. This display device differs from that configured according to the first embodiment in that the edge 16A-1 of the hole injection layer 16A or the same layer 16 as a whole contains a substance adapted to inhibit improved hole injection efficiency. Therefore, the differences will be primarily described below, and the description of the commonalities will be omitted as appropriate. It should be noted that FIG. 10 illustrates a case in which only the edge 16A-1 of the hole injection layer 16A (shaded area in FIG. 10) contains a substance adapted to inhibit improved hole injection efficiency.

In the present embodiment, a predetermined area of the hole injection layer 16A (edge 16A-1 or whole of the hole injection layer 16A) contains a substance adapted to inhibit improved hole injection efficiency. Among such inhibitors are the materials cited for use as the hole transporting layer 16B or electron transporting layer 16D in the first embodiment. Further, the hole injection layer 16A contains about several percent of such an inhibitor. Therefore, the portion of the hole injection layer 16A containing such an inhibitor is lower in conductivity than the portion not containing any inhibitor according to the magnitude of concentration of the inhibitor.

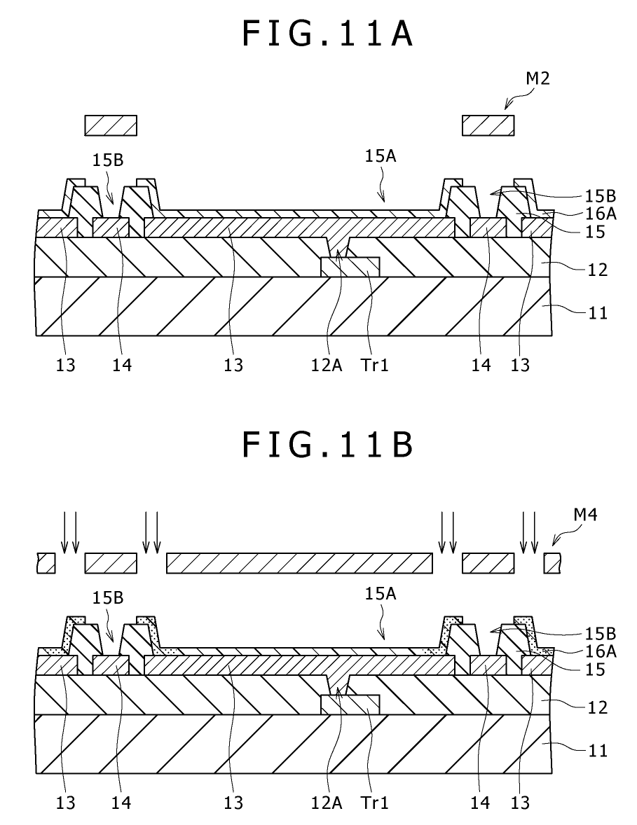

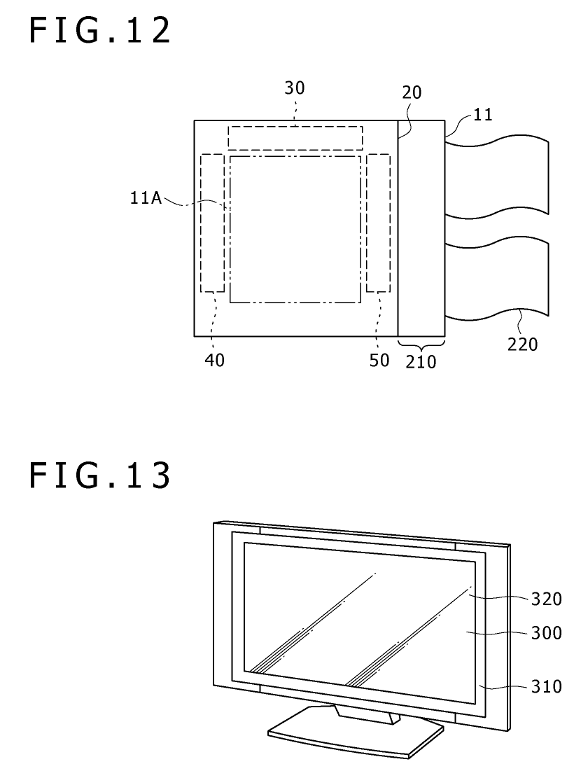

The hole injection layer 16A can be formed, for example, as described below. As illustrated in FIG. 11A, the mask M2 is disposed first. Next, the hole injection layer 16A is formed, for example, through vapor deposition at least on the exposed surface of the first electrode 13 in the first opening. It should be noted that FIG. 11A illustrates a case in which the hole injection layer 16A is formed on the exposed surface of the first electrode 13 in the opening 15A and part of the surface of the isolation insulating film 15. Then, as illustrated in FIG. 11B, the inhibitor is injected into the edge 16A-1 of the hole injection layer 16A, for example, through sputtering.

It should be noted that the hole injection layer 16A according to the present embodiment may be formed by other method. For example, an inhibitor can be contained throughout the hole injection layer 16A by vapor-depositing the material, cited for use as hole injection layer 16A, and the inhibitor together. In this case, the same mask as an existing one can be used for vapor deposition, thus contributing to reduced manufacturing cost.

In the present embodiment, the edge 16A-1 of the hole injection layer 16A contains a substance adapted to inhibit improved hole injection efficiency. Therefore, the edge 16A-1 is lower in conductivity than the middle portion according to the magnitude of concentration of the inhibitor. This allows for the high-resistance portion (edge 16A-1 of the hole injection layer 16A) to mediate between the middle portion of the hole injection layer 16A and the second electrode 17, thus keeping the low-resistance portion (middle portion of the hole injection layer 16A) and second electrode 17 out of contact with each other. This provides reduced current (leak current) flowing between the first and second electrodes 13 and 17 without flowing via the light-emitting layer 16C, thus preventing the deviation of the V-I characteristic from the ideal condition.

### MODULE AND APPLICATION EXAMPLES

A description will be given below of application examples of the display devices according to the above first to third embodiments. The display device according to any one of the above embodiments is applicable as a display of electronic equipment across all fields, including a television set, a digital camera, laptop personal computer, personal digital assistant such as mobile phone and video camcorder. These pieces of equipment are designed to display an image or video of a video signal fed to or generated inside the electronic equipment.

### (Module)

The display device according to any one of the above embodiments is incorporated as a module in a variety of electronic equipment described later in Application Examples 1 to 5. This module has, on one side of the substrate 11, an area 210 exposed from the sealing substrate 20 and adhesive layer 19. External connection terminals (not shown) are formed in the exposed area 210 by extending the wirings from the signal line drive circuit 30, scan line drive circuit 40 and power line drive circuit 50. A flexible printed circuit (FPC) 220, adapted to allow exchange of signals, may be provided on the external connection terminals.

### Application Example 1

FIG. 13 illustrates the appearance of a television set to which the display device according to any one of the above embodiments is applied. This television set includes, for example, a video display screen section 300 made up of a front panel 310 and filter glass 320. The video display screen section 300 includes the display device according to any one of the above embodiments.

### Application Example 2

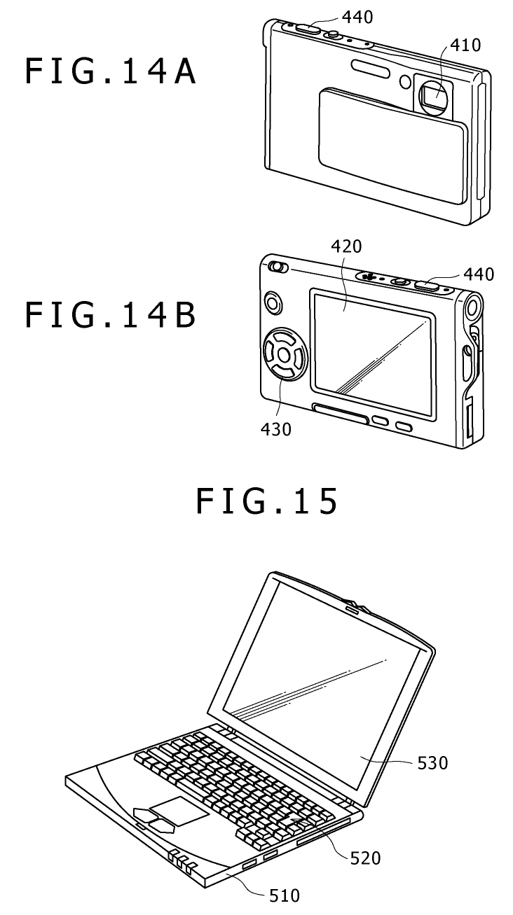

FIGS. 14A and 14B illustrate the appearance of a digital camera to which the display device according to any one of the above embodiments is applied. This digital camera includes, for example, a flash-emitting section 410, display section 420, menu switch 430 and shutter button 440. The display section 420 includes the display device according to any one of the above embodiments.

### Application Example 3

FIG. 15 illustrates the appearance of a laptop personal computer to which the display device according to any one of the above embodiments is applied. This laptop personal computer includes, for example, a main body 510, a keyboard 520 adapted to be manipulated for entry of text or other information and a display section 530 adapted to display an image. The display section 530 includes the display device according to any one of the above embodiments.

### Application Example 4

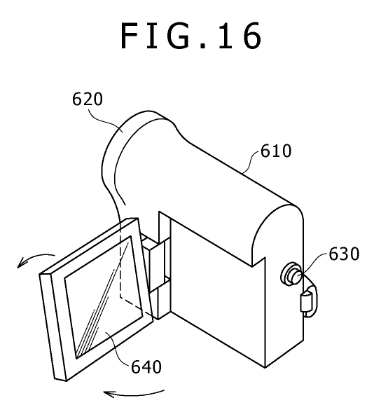

FIG. 16 illustrates the appearance of a video camcorder to which the display device according to any one of the above embodiments is applied. This video camcorder includes, for example, a main body section 610, lens 620 provided on the front-facing side surface of the main body section 610 to capture the subject image, imaging start/stop switch 630 and display section 640. The display section 640 includes the display device according to any one of the above embodiments.

### Application Example 5

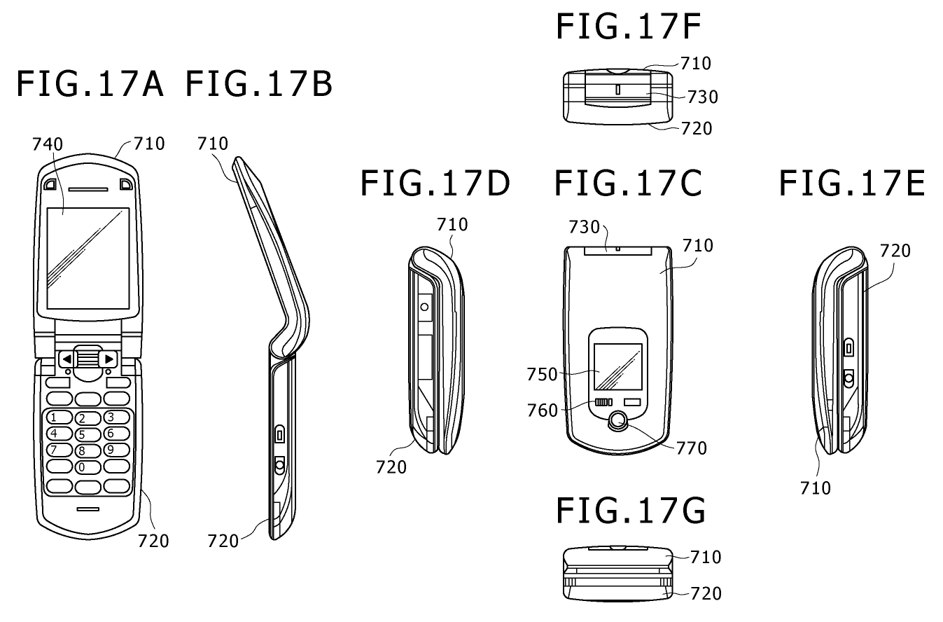

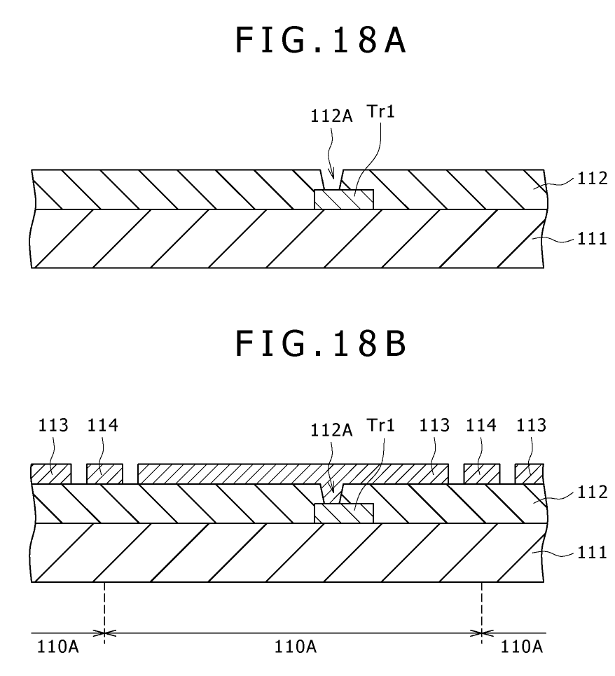

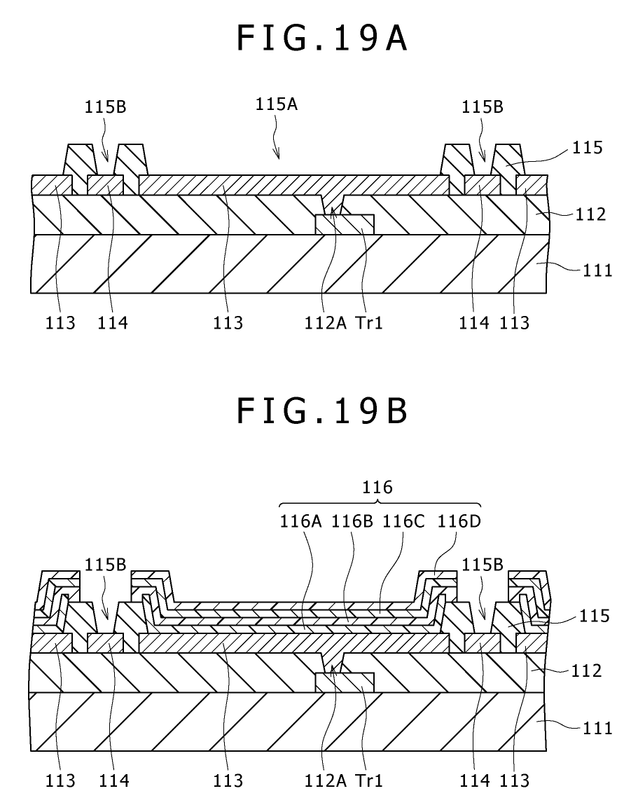

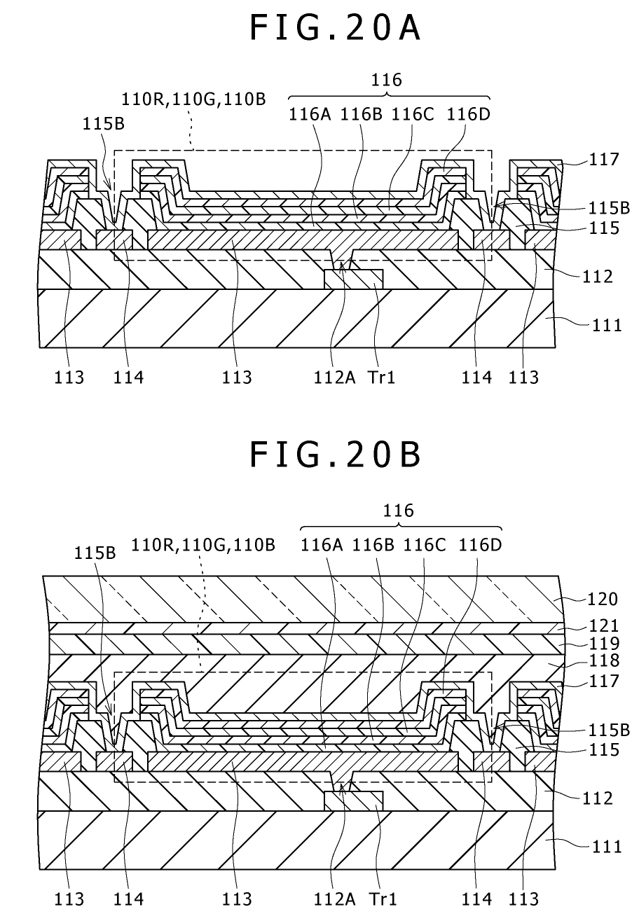

FIGS. 17A to 17G illustrate the appearance of a mobile phone to which the display device according to any one of the above embodiments is applied. This mobile phone has, for example, upper and lower enclosures 710 and 720 connected together with a connecting section (hinge section) 730 and includes a display 740, subdisplay 750, picture light 760 and camera 770. The display 740 or subdisplay 750 includes the display device according to any one of the above embodiments.

Although preferred embodiments of the present invention have been described above, the present invention is not limited to the foregoing embodiments but may be modified in various manners.

For example, the present invention is not limited to the materials and thicknesses of the layers or the forming methods and conditions described in the above embodiments. Instead, other materials and thicknesses of the layers or other forming methods and conditions may be used. In the above embodiments, a case was described in which the first electrode 13, organic layer 16 and second electrode 17 were stacked on the substrate 11 sequentially in this order from the side of the substrate 11 so as to extract light from the side of the sealing substrate 20. However, the stacking order may be, for example, reversed. That is, the second electrode 17, organic layer 16 and first electrode 13 may be stacked on the substrate 11 sequentially in this order from the side of the substrate 11 so as to extract light from the side of the substrate 11.

Further, in the above embodiments, a case was described in which the first electrode 13 served as an anode, and the second electrode 17 as a cathode. However, the functions of the first and second electrodes 13 and 17 may be reversed. That is, the first electrode 13 may serve as a cathode, and the second electrode 17 as an anode. Still further, in addition to using the first electrode 13 as a cathode, and the second electrode 17 as an anode, the second electrode 17, organic layer 16 and first electrode 13 may be stacked on the substrate 11 sequentially in this order from the side of the substrate 11 so as to extract light from the side of the substrate 11.

Still further, in the above embodiments, a specific description was given of the configuration of the organic light-emitting elements 10R, 10G and 10B. However, the same elements 10R, 10G and 10B need not have all the layers described. Alternatively, the same elements 10R, 10G and 10B may include other layers. For example, a thin film layer for hole injection may be provided between the first electrode 13 and organic layer 16. The thin film layer is made of chromium oxide (III) (Cr₂O₃), ITO (indium-tin oxide; mixture of indium (In) and tin (Sn) oxide) or other material. Still further, the first electrode 13 may be, for example, a dielectric multi-layer film.

Still further, in the above embodiments, a case was described in which the second electrode 17 included a semi-transmissive reflecting layer. However, the second electrode 17 may have a layered structure which includes a semi-transmissive reflecting layer and transparent electrode stacked in this order from the side of the first electrode 13. The transparent electrode is designed to ensure reduced resistance of the semi-transmissive reflecting layer and made of a conductive material highly transmitting for light produced by the light-emitting layer. The transparent electrode should preferably be made, for example, of ITO or a compound containing indium, zinc and oxygen. The reason for this is that excellent conductivity can be achieved even by forming the electrode at room temperature. The thickness of the transparent electrode may be, for example, between 30 nm and 1000 nm. Further, in this case, a resonator structure may be formed. In this resonator structure, the semi-transmissive reflecting layer serves as one of the end portions. The other end portion is provided where it faces the semi-transmissive reflecting layer, with the transparent electrode provided therebetween. The transparent electrode serves as a resonator section. Still further, with such a resonator structure provided, the organic light-emitting elements 10R, 10G and 10B should preferably be covered with the protective film 18 which is made of a material having a similar refractive index to that of the material making up the transparent electrode because the protective film 18 forms part of the resonator section.

Still further, the embodiments of the present invention are also applicable when the following resonator structure is formed. That is, the second electrode 17 includes a transparent electrode. The end surface of this transparent electrode on the opposite side of the organic layer 16 has a high reflectance. The end surface of the first electrode 13 on the side of the light-emitting layer 16C serves as a first end portion. The end surface of the transparent electrode on the opposite side of the organic layer serves as a second end portion. On the other hand, for example, the transparent electrode may be brought in contact with an atmospheric layer, and the reflectance of a boundary surface between the transparent electrode and atmospheric layer may be increased so that this boundary surface can be used as a second end portion. Alternatively, the reflectance of a boundary surface with the adhesive layer may be increased so that this boundary surface can be used as a second end portion. Still alternatively, the organic light-emitting elements 10R, 10G and 10B may be covered with the protective film 18, and the reflectance of a boundary surface with the same film 18 may be increased so that this boundary surface can be used as a second end portion.

Still further, although an active matrix display device was described in the above embodiments, the present invention is also applicable to a passive matrix display device. Moreover, the configuration of the pixel drive circuit for active matrix driving is not limited to those described in relation to the above embodiments, but rather capacitors and transistors may be added as necessary. In such a case, a necessary drive circuit may be added, in addition to the signal line drive circuit 30, scan line drive circuit 40 and power line drive circuit 50, to accommodate the change made to the pixel drive circuit.

The present application contains subject matter related to that disclosed in Japanese Priority Patent Application JP 2008-103823, filed in the Japan Patent Office on Apr. 11, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display element comprising:
a first electrode;
an auxiliary wiring formed on the periphery of the first electrode in such a manner as to be insulated from the first electrode;
an insulating portion having first and second openings, the first opening adapted to expose the first electrode, and the second opening adapted to expose the auxiliary wiring;
an organic layer adapted to cover the exposed surface of the first electrode in the first opening; and
a second electrode adapted to cover the organic layer and the exposed surface of the auxiliary wiring in the second opening, wherein
the organic layer has a layered structure which includes a hole injection layer and light-emitting layer stacked in this order from the side of the first electrode, and
the edge of the hole injection layer is provided more inward than the edge of the organic layer.

2. The display element of claim 1, wherein
the organic layer is formed through vapor deposition.

3. A display element comprising:
a first electrode;
an auxiliary wiring formed on the periphery of the first electrode in such a manner as to be insulated from the first electrode; and
an insulating portion having first and second openings, the first opening adapted to expose the first electrode, and the second opening adapted to expose the auxiliary wiring;
an organic layer adapted to cover the exposed surface of the first electrode in the first opening; and
a second electrode adapted to cover the organic layer and the exposed surface of the auxiliary wiring in the second opening, wherein
the organic layer has a layered structure which includes a hole injection layer and light-emitting layer stacked in this order from the side of the first electrode, and
the edge of the hole injection layer has higher resistance than the middle portion of the same layer.

4. The display element of claim 3, wherein
the edge of the hole injection layer is thinner than the middle portion of the same layer or contains a substance adapted to inhibit improved hole injection efficiency.

5. A display device comprising:
display elements; and
drive circuits adapted to drive the display elements;
each of the display elements including
a first electrode,
an auxiliary wiring formed on the periphery of the first electrode in such a manner as to be insulated from the first electrode,
an insulating portion having first and second openings, the first opening adapted to expose the first electrode, and the second opening adapted to expose the auxiliary wiring,
an organic layer adapted to cover the exposed surface of the first electrode in the first opening, and
a second electrode adapted to cover the organic layer and the exposed surface of the auxiliary wiring in the second opening, wherein
the organic layer has a layered structure which includes a hole injection layer and light-emitting layer stacked in this order from the side of the first electrode, and
the edge of the hole injection layer is provided more inward than the edge of the organic layer.

6. A display device comprising:
display elements; and
drive circuits adapted to drive the display elements;
each of the display elements including
a first electrode,
an auxiliary wiring formed on the periphery of the first electrode in such a manner as to be insulated from the first electrode,
an insulating portion having first and second openings, the first opening adapted to expose the first electrode, and the second opening adapted to expose the auxiliary wiring,
an organic layer adapted to cover the exposed surface of the first electrode in the first opening, and
a second electrode adapted to cover the organic layer and the exposed surface of the auxiliary wiring in the second opening, wherein
the organic layer has a layered structure which includes a hole injection layer and light-emitting layer stacked in this order from the side of the first electrode, and
the edge of the hole injection layer has higher resistance than the middle portion of the same layer.

7. A manufacturing method of a display element comprising the steps of:
forming, on a substrate, a first electrode and an auxiliary wiring on the edge of the first electrode in such a manner that the auxiliary wiring is insulated from the first electrode;
forming an insulating portion having a first opening adapted to expose the first electrode and a second opening adapted to expose the auxiliary wiring;
forming a hole injection layer adapted to cover the exposed surface of the first electrode in the first opening first, and then forming an organic layer, which is less conductive than the hole injection layer and which includes a light-emitting layer, in such a manner as to cover the hole injection layer; and
forming a second electrode adapted to cover the organic layer and the exposed surface of the auxiliary wiring in the second opening.

8. The manufacturing method of a display element of claim 7, wherein
the organic layer is formed through vapor deposition.

9. A manufacturing method of a display element comprising the steps of:
forming, on a substrate, a first electrode and an auxiliary wiring on the edge of the first electrode in such a manner that the auxiliary wiring is insulated from the first electrode;
forming an insulating portion having a first opening adapted to expose the first electrode and a second opening adapted to expose the auxiliary wiring;
forming a hole injection layer adapted to cover the exposed surface of the first electrode in the first opening and at the same time providing the edge of the hole injection layer with higher resistance than the middle portion of the same layer;
forming an organic layer, which is less conductive than the hole injection layer and which includes a light-emitting layer, on the hole injection layer; and
forming a second electrode adapted to cover the organic layer and the exposed surface of the auxiliary wiring in the second opening.
